(19) United States
(12) Patent Application Publication
(10) Pub. No.: US 2026/0066482 A1
(43) Pub. Date: Mar. 5, 2026

(54) CONDUCTIVE MODULE

(71) Applicant: Yazaki Corporation, Tokyo (JP)

(72) Inventor: Makoto Ogawa, Makinohara-shi (JP)

(21) Appl. No.: 19/312,749

(22) Filed: Aug. 28, 2025

(30) Foreign Application Priority Data
Aug. 30, 2024 (JP) 2024-148211

(51) Int. Cl. H01M 50/519; H01M 10/42; H01M 10/48; H01M 50/503; H05K 1/02

(52) U.S. Cl. CPC H01M 50/519; H01M 10/425; H01M 10/482; H01M 50/503; H05K 1/0277; H01M 2010/4271; H05K 2201/10356

(57) ABSTRACT

A conductive module includes a bus bar that is physically and electrically connected to an electrode terminal of a battery cell, a flexible printed circuit that is molded in a rectangular shape extending in an arrangement direction of the plurality of battery cells, and electrically connects between a battery monitoring unit and the bus bar, and an electric wire for each of the bus bars that has flexibility and electrically connects the bus bar to the flexible printed circuit. The flexible printed circuit includes a circuit conductor for each of the bus bars that electrically connects the bus bar to the battery monitoring unit, and a pad portion for each of the bus bars that is provided adjacent to the bus bar and is electrically connected to the circuit conductor for the bus bar.

### CROSS-REFERENCE TO RELATED APPLICATION(S)

The present application claims priority to and incorporates by reference the entire contents of Japanese Patent Application No. 2024-148211 filed in Japan on Aug. 30, 2024.

### BACKGROUND OF THE INVENTION

### 1. Field of the Invention

The present invention relates to a conductive module.

### 2. Description of the Related Art

The conductive module is a wiring module that electrically connects a battery module in which a plurality of battery cells is arranged and a battery monitoring unit that monitors a battery state of the battery cells. The conductive module includes a bus bar that is physically and electrically connected to electrode terminals of one or a pair of battery cells of the battery module, and a flexible printed circuit that electrically connects the plurality of bus bars and the battery monitoring unit. Here, in the battery module, due to thermal expansion and thermal contraction of the battery cells, manufacturing tolerance variations of the battery cells, and assembly tolerance variations of the plurality of battery cells, the pitch between the electrode terminals of the adjacent battery cells deviates within a range of design tolerance. At this time, in the battery module, the position of the electrode terminal with respect to the flexible printed circuit is relatively shifted within the range of design tolerance. Therefore, in the conventional conductive module, a flexible printed circuit provided with a trunk line and a branch line branched from the trunk line for each bus bar is used, and the branch line having a three-dimensional shape bent in an S shape or the like is connected to the bus bar, so that misalignment of the electrode terminal is absorbed by the branch line. This type of conductive module is disclosed in, for example, Japanese Patent Application Laid-open No. JP 2020-205175 A and Japanese Patent Application Laid-open No. JP 2022-173610 A.

By the way, in the conventional conductive module, since a flexible printed circuit in which a branch line is branched for each bus bar from a rectangular and flat plate-shaped trunk line is used, a yield is deteriorated when a plurality of flexible printed circuits are manufactured from one sheet. In the conventional conductive module, since the branch line protruding from the trunk line is formed in a three-dimensional shape and connected to the bus bar, in addition to an installation space of the branch line only for connecting the trunk line and the bus bar, a space for exerting the tolerance absorption function by the branch line is required, and there is a possibility that the size is increased.

### SUMMARY OF THE INVENTION

Therefore, an object of the present invention is to provide a conductive module having a good yield while suppressing an increase in size.

In order to achieve the above mentioned object, a conductive module according to one aspect of the present invention includes a bus bar that is physically and electrically connected to an electrode terminal of one or a pair of battery cells in a battery module in which a plurality of battery cells is arranged; a flexible printed circuit that is molded in a rectangular shape extending in an arrangement direction of the plurality of battery cells, and electrically connects between a battery monitoring unit that monitors a battery state of the battery cells and the bus bar; and an electric wire for each of the bus bars that has flexibility and electrically connects the bus bar to the flexible printed circuit; wherein the flexible printed circuit includes a circuit conductor for each of the bus bars that electrically connects the bus bar to the battery monitoring unit, and a pad portion for each of the bus bars that is provided adjacent to the bus bar and is electrically connected to the circuit conductor for the bus bar, and one end of the electric wire is physically and electrically connected to an electric wire connecting portion on the bus bar side, and the other end of the electric wire is physically and electrically connected to the pad portion for the bus bar.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a perspective view illustrating a conductive module according to an embodiment;

FIG. 2 is a plan view illustrating the conductive module according to the embodiment;

FIG. 3 is a plan view of the conductive module according to the embodiment as viewed from another angle;

FIG. 4 is an exploded perspective view illustrating the conductive module of the embodiment;

FIG. 5 is an explanatory view for explaining the conductive module in which misalignment occurs between the conductive module and an electrode terminal;

FIG. 6 is an explanatory view for explaining the conductive module in which misalignment occurs between the conductive module and an electrode terminal;

FIG. 7 is an explanatory view for explaining the conductive module in which misalignment occurs between the conductive module and an electrode terminal; and

FIG. 8 is an explanatory view for explaining a yield of a flexible printed circuit.

### DETAILED DESCRIPTION OF THE PREFERRED EMBODIMENTS

Hereinafter, an embodiment of a conductive module according to the present invention will be described in detail with reference to the drawings. Note that the present invention is not limited by the embodiment.

### EMBODIMENT

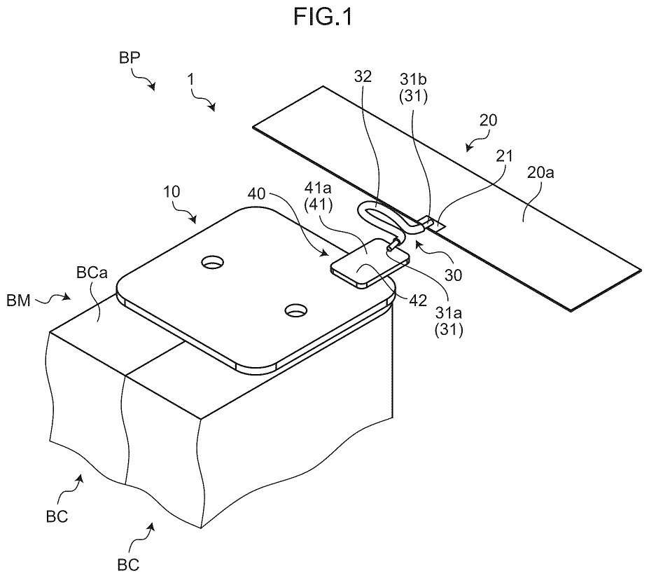

An embodiment of the conductive module according to the present invention will be described with reference to FIGS. 1 to 8.

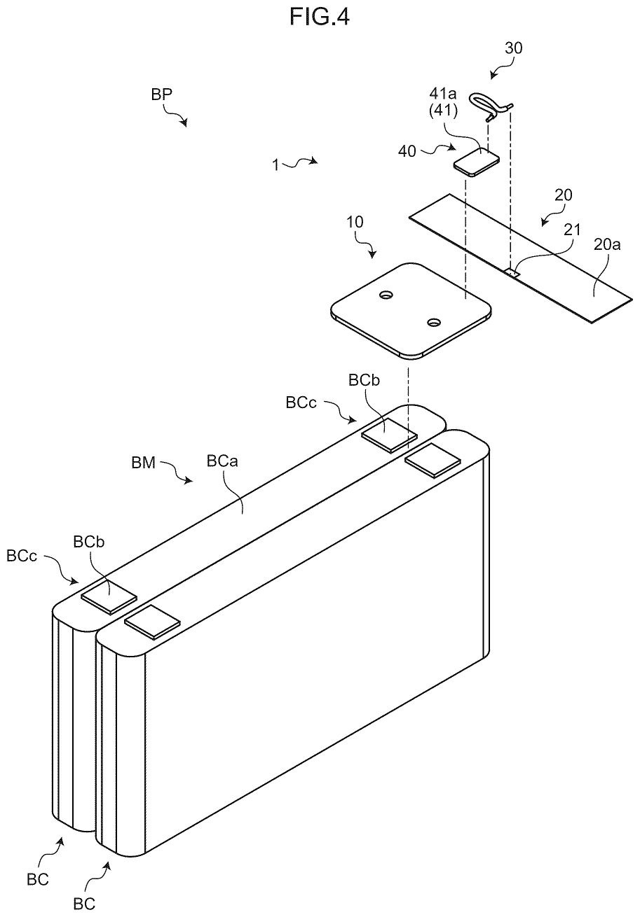

Reference numeral 1 in FIGS. 1 to 7 denotes a conductive module of the present embodiment. The conductive module 1 is assembled to a battery module BM (FIGS. 1 and 4) in which a plurality of battery cells BC are arranged (e.g., arranged in a single row), and the plurality of battery cells BC in the battery module BM are electrically connected. In addition, the conductive module 1 electrically connects the battery module BM to a battery monitoring unit (not illustrated) to cause the battery monitoring unit to monitor the battery state (voltage or the like) of the battery cell BC. The conductive module 1 constitutes a battery pack BP together with the battery module BM (FIGS. 1 and 4). The battery pack BP is mounted on, for example, a vehicle (BEV: Battery Electric Vehicle, HEV: Hybrid Electric Vehicle, etc.) including a rotary machine as a drive source, and is used for power supply to the rotary machine. The battery module BM in the drawing is obtained by extracting a part of the plurality of battery cells BC.

The battery cell BC includes a cell body BCa and positive and negative electrode terminals BCb (FIG. 4). In the battery cell BC illustrated here, the cell body BCa is formed in a cube having six outer wall surfaces. Then, in the plurality of battery cells BC constituting the battery module BM, the cell bodies BCa adjacent to each other in the arrangement direction are arranged with one outer wall surface facing each other. The battery module BM includes an electrode terminal group BCc on one side in which the electrode terminal BCb on one side in each battery cell BC is arranged along the arrangement direction, and the other electrode terminal group BCc in which the electrode terminal BCb on the other side in each battery cell BC is arranged along the arrangement direction (FIG. 4).

Hereinafter, in a case where the term “arrangement direction” is stated without any particular remark, it refers to the arrangement direction of the plurality of battery cells BC and the arrangement direction of the plurality of electrode terminals BCb in the electrode terminal group BCc.

In this example, each battery cell BC includes positive and negative electrode terminals BCb on one of the six outer wall surfaces of the cell body BCa (FIG. 4). Therefore, in the battery module BM, two electrode terminal groups BCc are provided on one flat surface (FIG. 4).

Further, the electrode terminal BCb illustrated here is formed in a flat plate shape, and is physically and electrically connected to a bus bar 10 to be described later by welding or the like (FIG. 4). However, the electrode terminal BCb may be formed in a pole shape having a male screw portion. In this case, the bus bar 10 is screwed and fixed to the electrode terminal BCb by screwing a female screw member to the male screw portion of the electrode terminal BCb.

The conductive module 1 includes a bus bar 10 that is physically and electrically connected to the electrode terminal BCb of one or a pair of battery cells BC in the battery module BM (FIGS. 1 to 4).

The bus bar 10 is formed of a conductive material such as metal. The bus bar 10 is a plate-like conductive component made of metal, and is press-molded using, for example, a metal plate as a base material. The bus bar 10 illustrated here is formed in a rectangular flat plate shape and is physically and electrically connected to the electrode terminal BCb by laser welding.

The bus bar 10 includes one that is physically and electrically connected to one electrode terminal BCb serving as the total negative electrode in the battery module BM and one that is physically and electrically connected to one electrode terminal BCb serving as the total positive electrode in the battery module BM. In addition, the bus bar 10 includes one that is physically and electrically connected to the electrode terminals BCb adjacent in the arrangement direction of the pair of battery cells BC in the battery module BM.

The conductive module 1 includes a flexible printed circuit (FPC) 20 that is molded in a rectangular shape extending in the arrangement direction and electrically connects between the bus bar 10 and the battery monitoring unit (FIGS. 1 to 4).

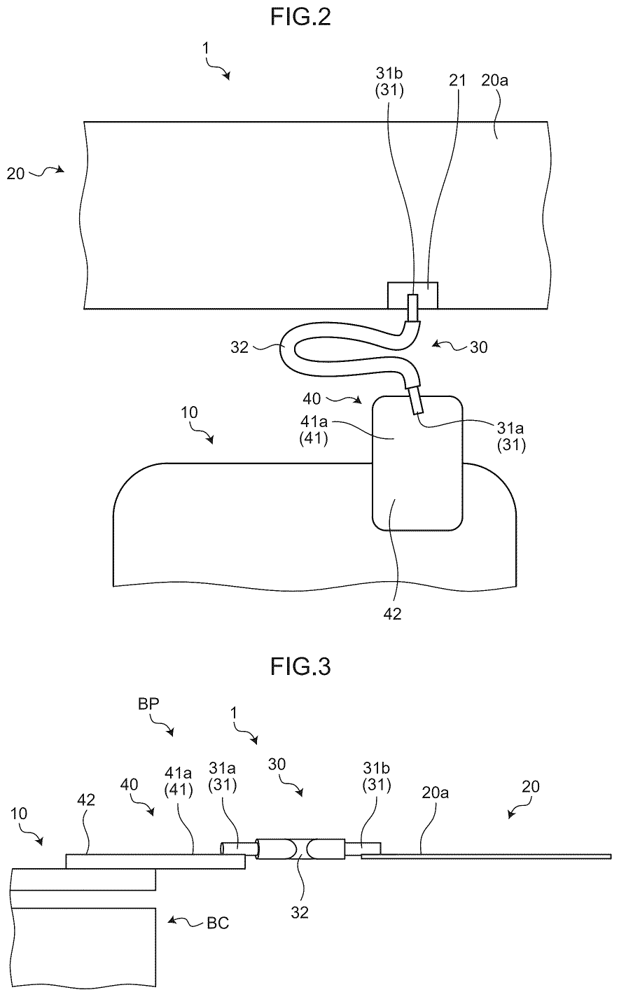

The flexible printed circuit 20 includes a circuit conductor for each bus bar 10 that electrically connects the bus bar 10 to the battery monitoring unit (not illustrated). On the flexible printed circuit 20, the circuit conductor is formed of a conductor pattern such as a copper foil. The flexible printed circuit 20 includes various films (base film and cover film) formed flat with flexibility as insulating coatings, and a conductor pattern is formed on at least one (base film) of the various films. The conductor pattern (circuit conductor) is enclosed by an insulating coating. Therefore, the flexible printed circuit 20 includes a pad portion 21 for each bus bar 10 provided adjacent to the bus bar 10 and electrically connected to the circuit conductor for the bus bar 10 as an electrical contact with the bus bar 10 side (FIGS. 1 and 2).

The conductive module 1 includes an electric wire 30 for each of the bus bars 10 having flexibility and electrically connecting the bus bar 10 to the flexible printed circuit 20 (FIGS. 1 to 4). One end of the electric wire 30 is physically and electrically connected to an electric wire connecting portion 41 on the bus bar 10 side, and the other end is physically and electrically connected to the pad portion 21 for the bus bar 10, thereby electrically connecting the bus bar 10 to the circuit conductor for the bus bar 10.

The electric wire 30 includes a core wire 31 and a sheath 32 covering the core wire 31 (FIGS. 1 to 3). The electric wire 30 includes a first core wire exposed portion 31a in which one end of the core wire 31 is exposed at one end and a second core wire exposed portion 31b in which the other end of the core wire 31 is exposed at the other end (FIGS. 1 to 3).

The electric wire connecting portion 41 is formed in a flat plate shape and protrudes to the outside of the battery module BM in a protruding direction orthogonal to the arrangement direction (FIG. 1). A direction orthogonal to an extending direction of the flexible printed circuit 20 is defined as a width direction, the width direction is aligned with a protruding direction of the electric wire connecting portion 41, and the flat surface 20a on one side of the flexible printed circuit 20 is placed next to the battery module BM on the same plane as the flat surface 41a on one side of the electric wire connecting portion 41 (FIGS. 1 to 3). The flexible printed circuit 20 is arranged at an interval with respect to the electric wire connecting portion 41 in the width direction thereof.

The electric wire 30 is disposed between the electric wire connecting portion 41 and the flexible printed circuit 20 to electrically connect the flat surface 41a on one side of the electric wire connecting portion 41 and the pad portion 21 of the flat surface 20a on one side of the flexible printed circuit 20. The electric wire 30 is bent on the same plane as the flat surfaces 41a and 20a on one side in each of the electric wire connecting portion 41 and the flexible printed circuit 20 (FIGS. 1 to 3). In addition, the electric wire 30 physically and electrically connects the first core wire exposed portion 31a at one end to the flat surface 41a on one side of the electric wire connecting portion 41, and physically and electrically connects the second core wire exposed portion 31b at the other end to the pad portion 21 of the flat surface 20a on one side of the flexible printed circuit 20 (FIGS. 1 to 3). Here, the electric wire 30 is bent in a U shape.

For example, the electric wire connecting portion 41 illustrated here is provided as a part of a bus bar connecting terminal 40 which is physically and electrically connected to the bus bar 10 (FIGS. 1 to 4). The bus bar connecting terminal 40 includes an electric wire connecting portion 41 that physically and electrically connects the first core wire exposed portion 31a at one end of the electric wire 30, and a bus bar connecting portion 42 that physically and electrically connects the bus bar 10 (FIGS. 1 to 3). For example, the bus bar connecting terminal 40 is formed in a flat plate shape linearly connecting the electric wire connecting portion 41 and the bus bar connecting portion 42 using a metal plate as a base material. In this example, the bus bar connecting terminal 40 is formed in a rectangular flat plate shape whose longitudinal direction is the linear direction, and the electric wire connecting portion 41 protrudes to the outside of the battery module BM along the longitudinal direction.

In the bus bar connecting terminal 40, the bus bar connecting portion 42 in the other plane is placed on the plane of the bus bar 10 with the longitudinal direction aligned with the direction orthogonal to the arrangement direction, and the bus bar connecting portion 42 and the bus bar 10 are physically and electrically connected by, for example, laser welding. Thus, in the bus bar connecting terminal 40, the electric wire connecting portion 41 protrudes to the outside of the battery module BM in the direction orthogonal to the arrangement direction. In the electric wire connecting portion 41, the first core wire exposed portion 31a at one end of the electric wire 30 is placed on the flat surface 41a on one side, and the first core wire exposed portion 31a is physically and electrically connected by, for example, soldering or the like. Then, in the electric wire 30, the second core wire exposed portion 31b at the other end is placed on the pad portion 21 of the flat surface 20a on one side of the flexible printed circuit 20, and the second core wire exposed portion 31b is physically and electrically connected to the pad portion 21 by, for example, soldering or the like.

Incidentally, the electric wire connecting portion 41 may be provided as a part of the bus bar 10 (not illustrated). In this case, the bus bar 10 is provided with a bus bar body which is physically and electrically connected to the electrode terminal BCb by laser welding, and an electric wire connecting portion 41 which protrudes from the bus bar body.

Here, as described above, in the battery module BM, the position of the electrode terminal BCb may be relatively shifted with respect to the flexible printed circuit 20 within the range of the design tolerance. In the conductive module 1 of the present embodiment, since the battery module BM side where the bus bar 10 is connected to the electrode terminal BCb and the flexible printed circuit 20 are connected by the flexible electric wire 30, the misalignment of the electrode terminal BCb can be absorbed by the electric wire 30.

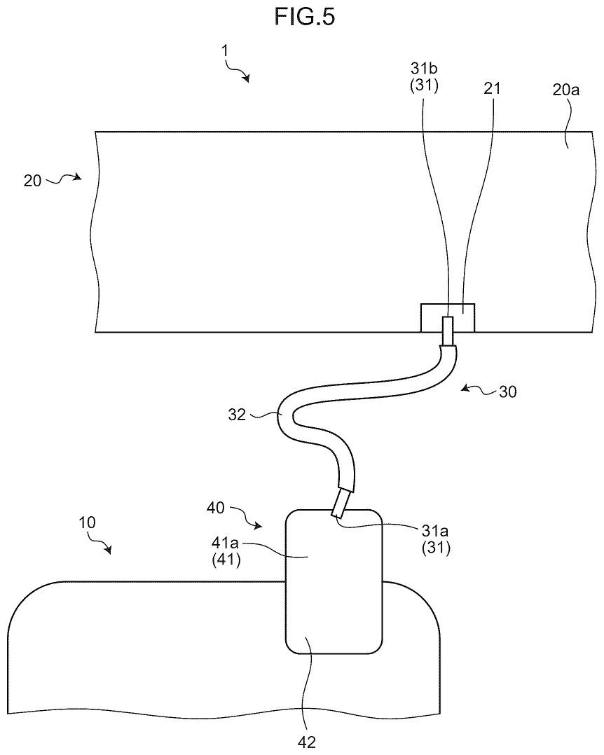

Specifically, in the conductive module 1, in a case where the electrode terminal BCb is relatively misaligned in one direction in the arrangement direction with respect to the flexible printed circuit 20 due to thermal expansion of the battery cell BC or the like, the shape of the electric wire 30 is changed in accordance with the relative movement, whereby the misalignment of the electrode terminal BCb can be followed (FIG. 5). Note that, in the conductive module 1, even in a case where the electrode terminal BCb is relatively misaligned in the width direction of the flexible printed circuit 20 with respect to the flexible printed circuit 20 due to thermal expansion of the battery cell BC or the like, the shape of the electric wire 30 is changed in accordance with the relative movement, whereby the misalignment of the electrode terminal BCb can be followed. In the conductive module 1 of FIG. 5, a case where the electrode terminal BCb is relatively misaligned with respect to the flexible printed circuit 20 in one direction in the arrangement direction and the width direction of the flexible printed circuit 20 is illustrated.

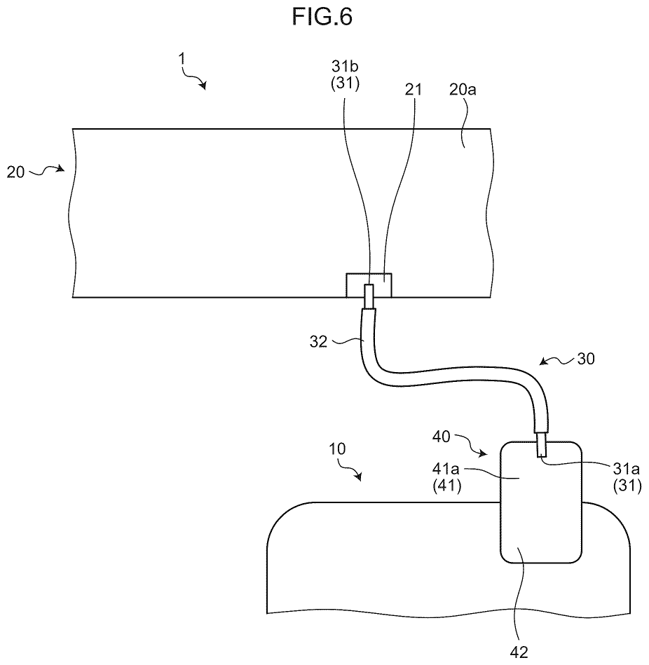

In addition, in the conductive module 1, in a case where the electrode terminal BCb is relatively misaligned in the other direction in the arrangement direction with respect to the flexible printed circuit 20 due to thermal expansion of the battery cell BC or the like, the shape of the electric wire 30 is changed in accordance with the relative movement, whereby the misalignment of the electrode terminal BCb can be followed (FIG. 6). In the conductive module 1 of FIG. 6, a case where the electrode terminal BCb is relatively misaligned with respect to the flexible printed circuit 20 in the other direction in the arrangement direction and the width direction of the flexible printed circuit 20 is illustrated.

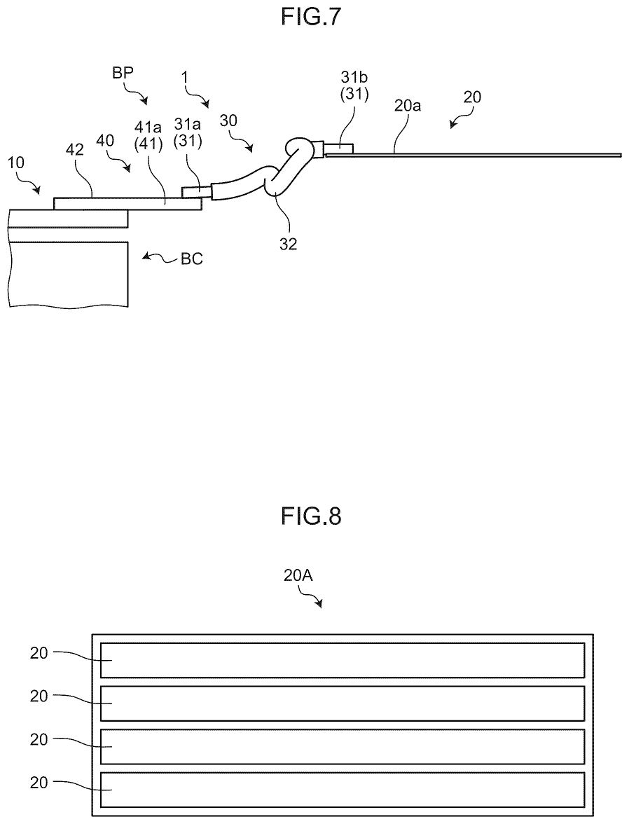

In addition, in the conductive module 1, in a case where the electrode terminal BCb is relatively misaligned in a direction orthogonal to the plane of the electrode terminal BCb with respect to the flexible printed circuit 20 due to thermal expansion of the battery cell BC or the like, the shape of the electric wire 30 is changed in accordance with the relative movement, whereby the misalignment of the electrode terminal BCb can be followed (FIG. 7). FIG. 7 illustrates the movement of the electric wire 30 when the misalignment of the electrode terminal BCb in one direction in the orthogonal direction occurs. Although not illustrated here, even when the misalignment of the electrode terminal BCb in the other direction in the orthogonal direction occurs, the shape of the electric wire 30 is changed in accordance with the relative movement of the electrode terminal BCb and the flexible printed circuit 20, whereby the misalignment of the electrode terminal BCb can be followed.

Furthermore, in the conductive module 1, even if the position of the electrode terminal BCb with respect to the flexible printed circuit 20 is relatively misaligned in the arrangement direction due to manufacturing tolerance variations of the battery cells BC or assembly tolerance variations of the plurality of battery cells BC, the shape of the electric wire 30 can be changed in accordance with the misalignment of the electrode terminal BCb, so that accurate assembly with respect to the battery module BM can be performed.

In addition, in the conductive module 1, even if the position of the electrode terminal BCb with respect to the flexible printed circuit 20 is relatively misaligned in the width direction of the flexible printed circuit 20 due to manufacturing tolerance variations of the battery cells BC or assembly tolerance variations of the plurality of battery cells BC, the shape of the electric wire 30 can be changed in accordance with the misalignment of the electrode terminal BCb, so that accurate assembly with respect to the battery module BM can be performed.

To exemplify with reference to FIGS. 5 and 6, the position of the electrode terminal BCb with respect to the flexible printed circuit 20 is relatively misaligned in the arrangement direction and the width direction of the flexible printed circuit 20 due to manufacturing tolerance variations of the battery cells BC and assembly tolerance variations of the plurality of battery cells BC. Even in such a case, in the conductive module 1, since the shape of the electric wire 30 can be changed in accordance with the misalignment of the electrode terminal BCb, accurate assembly to the battery module BM can be performed.

In addition, in the conductive module 1, even if the position of the electrode terminal BCb with respect to the flexible printed circuit 20 is relatively misaligned in the direction orthogonal to the plane of the electrode terminal BCb due to manufacturing tolerance variations of the battery cells BC or assembly tolerance variations of the plurality of battery cells BC, the shape of the electric wire 30 can be changed in accordance with the misalignment of the electrode terminal BCb, so that accurate assembly with respect to the battery module BM can be performed (FIG. 7).

As described above, the conductive module 1 according to the present embodiment, since the tolerance absorption function is carried by the flexible electric wire 30 in three directions orthogonal to each other, the tolerance absorption function is not necessarily carried by each branch line as in the conventional case, and it is not necessary to provide a space for the branch line to exert the tolerance absorption function. Therefore, the conductive module 1 of the present embodiment can obtain the tolerance absorption function that suppresses an increase in size. In particular, in the conductive module 1 illustrated here, the flat surfaces 41a and 20a on one side of each of the electric wire connecting portion 41 and the flexible printed circuit 20 are arranged on the same plane, and the electric wire 30 is bent on the same plane as the flat surfaces 41a and 20a on one side thereof, so that it is possible to more effectively suppress an increase in size. Further, in the conductive module 1 according to the present embodiment, since the flexible printed circuit 20 is formed in a rectangular flat plate shape, a yield is good when a plurality of flexible printed circuits 20 are manufactured from one sheet 20A (FIG. 8). As described above, the conductive module 1 according to the present embodiment may obtain the tolerance absorption function that suppresses an increase in size and improves yield.

In the conductive module according to the present embodiment, since the tolerance absorption function is carried by the flexible electric wire, the tolerance absorption function is not necessarily carried by each branch line as in the conventional case, and it is not necessary to provide a space for the branch line to exert the tolerance absorption function. Therefore, the conductive module can obtain a tolerance absorption function that suppresses an increase in size. Further, in the conductive module according to the present embodiment, since the flexible printed circuit is formed in a rectangular flat plate shape, a yield is good when a plurality of flexible printed circuits are manufactured from one sheet. As described above, the conductive module according to the present embodiment can obtain the tolerance absorption function that suppresses an increase in size and improves yield.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A conductive module comprising:
a bus bar that is physically and electrically connected to an electrode terminal of one or a pair of battery cells in a battery module in which a plurality of battery cells is arranged;
a flexible printed circuit that is molded in a rectangular shape extending in an arrangement direction of the plurality of battery cells, and electrically connects between a battery monitoring unit that monitors a battery state of the battery cells and the bus bar; and
an electric wire for each of the bus bars that has flexibility and electrically connects the bus bar to the flexible printed circuit; wherein
the flexible printed circuit includes a circuit conductor for each of the bus bars that electrically connects the bus bar to the battery monitoring unit, and a pad portion for each of the bus bars that is provided adjacent to the bus bar and is electrically connected to the circuit conductor for the bus bar, and
one end of the electric wire is physically and electrically connected to an electric wire connecting portion on the bus bar side, and the other end of the electric wire is physically and electrically connected to the pad portion for the bus bar.

2. The conductive module according to claim 1, wherein
the electric wire connecting portion is formed in a flat plate shape and protrudes to an outside of the battery module in a protruding direction orthogonal to the arrangement direction,
a width direction orthogonal to an extending direction of the flexible printed circuit is aligned with the projecting direction of the flexible printed circuit, and one plane of the flexible printed circuit is disposed adjacently to the battery module on the same plane as one plane of the electric wire connecting portion, and
the electric wire is bent on the same plane as one of the planes of the electric wire connecting portion and the flexible printed circuit, and then the one end is physically and electrically connected to the one plane of the electric wire connecting portion, and the other end is physically and electrically connected to the pad portion of the one plane of the flexible printed circuit.

3. The conductive module according to claim 1, wherein
the electric wire connecting portion is provided as a part of the bus bar.

4. The conductive module according to claim 2, wherein
the electric wire connecting portion is provided as a part of the bus bar.

5. The conductive module according to claim 1, wherein
the electric wire connecting portion is provided as a part of a bus bar connecting terminal which is physically and electrically connected to the bus bar.

6. The conductive module according to claim 2, wherein
the electric wire connecting portion is provided as a part of a bus bar connecting terminal which is physically and electrically connected to the bus bar.
